(19) United States
(12) Patent Application Publication
(10) Pub. No.: US 2012/0305920 A1
(43) Pub. Date: Dec. 6, 2012

(54) SEMICONDUCTOR DEVICE AND MANUFACTURING METHOD THEREOF, DISPLAY APPARATUS AND ELECTRONIC APPARATUS

(75) Inventors: Koichi Nagasawa, Aichi (JP); Masanobu Ikeda, Kanagawa (JP); Yasuhiro Murata, Aichi (JP)

(73) Assignee: SONY CORPORATION, Tokyo (JP)

(21) Appl. No.: 13/469,344

(22) Filed: May 11, 2012

(30) Foreign Application Priority Data
May 30, 2011 (JP) 2011-120490

(51) Int. Cl. H01L 29/786; H01L 21/768; H01L 27/15

(52) U.S. Cl. 257/57; 257/66; 257/88; 438/667; 257/E29.291; 257/E29.294; 257/E27.12; 257/E21.585

(57) ABSTRACT

A semiconductor device including: a first electric conductor of a lower layer side and a second electric conductor of an upper layer side; a thick film insulating layer provided between the first electric conductor and the second electric conductor; and a contact portion formed so as to imitate an inner surface shape of a through hole with respect to the insulating layer and electrically connecting the first electric conductor and the second electric conductor, in which a tapered angle of the through hole is an acute angle.

### CROSS REFERENCES TO RELATED APPLICATIONS

The present application claims priority to Japanese Priority Patent Application JP 2011-120490 filed in the Japan Patent Office on May 30, 2011, the entire content of which is hereby incorporated by reference.

### BACKGROUND

The present disclosure relates to a semiconductor device having a contact portion electrically connecting electric conductors to each other and a manufacturing method thereof, as well as a display apparatus and electronic apparatus provided with such a semiconductor device (semiconductor circuit portion).

Hitherto, for example, display apparatuses using display elements of a variety of types of liquid crystal elements and organic EL (Electro Luminescence) elements have been developed. In such display apparatuses, in general, a peripheral circuit is disposed in a frame region (non-display region) positioned at the outer edge (outer circumference) of a display region (effective display region) having a plurality of pixels. In addition, the pixel circuits and peripheral circuits between each of these pixels are configured using a semiconductor device (a semiconductor element of a thin film transistor (TFT) or the like). In such a semiconductor device (semiconductor circuit portion), in general, a contact portion for electrically connecting electric conductors to each other is formed in an insulating layer (dielectric layer) (for example, refer to Japanese Unexamined Patent Application Publication No. 6-242433, Japanese Unexamined Patent Application Publication No. 11-125831, and Japanese Unexamined Patent Application Publication No. 2002-98995).

### SUMMARY

Here, in the above-described contact portion, when a disconnection (connection defect) or an increase in the resistance value (contact resistance) occurs, the electrical connectivity deteriorates and the yield during manufacturing is decreased. Therefore, there is a demand for a proposal of a method for making it possible to perform electrical connection in the contact portion more reliably than previously, and to improve reliability.

It is desirable to provide a semiconductor device capable of improving reliability and a manufacturing method thereof, a display apparatus and an electronic apparatus.

A semiconductor device of an embodiment of the present disclosure includes: a first electric conductor of a lower layer side and a second electric conductor of an upper layer side; a thick film insulating layer provided between the first electric conductor and the second electric conductor; and a contact portion formed so as to imitate the inner surface shape of a through hole with respect to the insulating layer and electrically connecting the first electric conductor and the second electric conductor, in which the tapered angle of the through hole is an acute angle.

A manufacturing method of a semiconductor device of an embodiment of the present disclosure includes: forming a first electric conductor on a substrate; forming a thick film insulating layer on the first electric conductor; forming a through hole in which the tapered angle is an acute angle in the insulating layer; forming a contact portion electrically connecting with the first electric conductor so as to imitate the inner surface shape of the through hole; and forming a second electric conductor electrically connected to the first electric conductor through the contact portion on the insulating layer.

A display apparatus of an embodiment of the present disclosure is provided with a display unit, and the semiconductor device (semiconductor circuit unit) of the above-described present disclosure.

An electronic apparatus of an embodiment of the present disclosure is provided with the display apparatus of the above-described present disclosure.

In the semiconductor device, the manufacturing method thereof, the display apparatus and the electronic apparatus of an embodiment of the present disclosure, a contact portion electrically connecting the first electric conductor and the second electric conductor is formed so as to imitate the inner surface shape of the through hole for which the tapered angle is an acute angle with respect to the insulating layer. In this manner, even if the insulating layer has a thick film shape, the covering property of the through hole inner surface of the contact portion is improved, and a disconnection (connection defect) or an increase in the resistance value (contact resistance) in the contact portion may be suppressed.

According to the semiconductor device, the manufacturing method thereof, the display apparatus and the electronic apparatus of an embodiment of the present disclosure, since a contact portion electrically connecting the first electric conductor and the second electric conductor is formed so as to imitate the inner surface shape of the through hole for which the tapered angle is an acute angle with respect to the insulating layer, even if the insulating layer has a thick film shape, it is possible to suppress a disconnection or an increase in the resistance value in the contact portion. Accordingly, it is possible to perform electrical connection in the contact portion more reliably, and to improve reliability.

Additional features and advantages are described herein, and will be apparent from the following Detailed Description and the figures.

### BRIEF DESCRIPTION OF THE FIGURES

FIG. 1 is a diagram for describing an operation principle of a display apparatus having a touch sensor attached and shows a state when not in contact with a finger.

FIG. 2 is a diagram for describing an operation principle of a display apparatus having a touch sensor attached and shows a state when in contact with a finger.

FIGS. 3A and 3B are diagrams for describing an operation principle of a display apparatus having a touch sensor attached and show examples of waveforms of a driving signal and detection signal of the touch sensor.

FIG. 4 is a cross-sectional view representing a schematic configuration example of a display apparatus (display apparatus having a touch sensor attached) provided with the semiconductor device (semiconductor circuit portion) according to an embodiment of the present disclosure.

FIG. 5 is a perspective view showing a configuration example of main portions (common electrodes and detection electrodes for sensors) of the display apparatus shown in FIG. 4.

FIG. 6 is a block diagram representing an example of the pixel structure and a detailed configuration of a driver in the display apparatus shown in FIG. 4.

FIG. 7 is a block diagram representing another example of the pixel structure and a detailed configuration of a driver in the display apparatus shown in FIG. 4.

FIG. 8 is a circuit diagram showing an example of a detection circuit in the display apparatus shown in FIG. 4.

FIG. 9 is a cross-sectional view representing a detailed configuration example in the display apparatus shown in FIG. 4.

FIG. 10 is a schematic diagram for describing the aspect ratio and the tapered angle in the contact portion shown in FIG. 9.

FIG. 11 is a schematic cross-sectional view for describing the shape of the planarized film before and after post baking.

FIGS. 12A and 12B are cross-sectional views representing an example of a forming method of the contact portion using halftone exposure.

FIGS. 13A and 13B are characteristic diagrams representing an example of the relationship between the aspect ratio and tapered angle in the contact portion and the contact resistance.

FIGS. 14A and 14B are cross-sectional views representing a configuration of the contact portion according to a comparative example.

FIGS. 15A and 15B are characteristic diagrams representing an example and the like of the relationship between the tapered angle in the contact portion and the contact defect rate.

FIG. 16 is a characteristic diagram representing an example of the relationship between the distance between a columnar spacer and the contact portion and the stress applied to the contact portion.

FIG. 17 is a view showing the results of examples 1 to 3 regarding image quality deterioration caused by stress.

FIG. 18 is a perspective view representing the external appearance seen from the front side (A) in the application example 1 of the display apparatus of an embodiment and the external appearance seen from the rear side (B).

FIG. 19A is a perspective view representing the external appearance seen from the front side of the application example 2 and

FIG. 19B is a perspective view representing the external appearance seen from the rear side.

FIG. 20 is a perspective view representing the external appearance of application example 3.

FIG. 21 is a perspective view representing the external appearance of application example 4.

FIG. 22A is a front view of an opened state of application example 5,

FIG. 22B is a side surface view thereof,

FIG. 22C is a front view of a closed state,

FIG. 22D is a left side surface view,

FIG. 22E is a right side surface view,

FIG. 22F is an upper surface view, and

FIG. 22G is a lower surface view.

### DETAILED DESCRIPTION

Below, embodiments of the present disclosure will be described in detail with reference to the accompanying drawings. The description will be given in the following order.

1. Basic Principles of the Touch Detection Method in the Display Apparatus having a Touch Sensor Attached
2. Embodiments (Example of a display apparatus having a touch sensor, in which the tapered angle of the contact portion is an acute angle, attached)
3. Application Examples (Application examples for the electronic apparatus of the display apparatus)
4. Modification Examples (Application examples and the like for the semiconductor device other than the display apparatus)

### <Basic Principles of the Touch Detection Method>

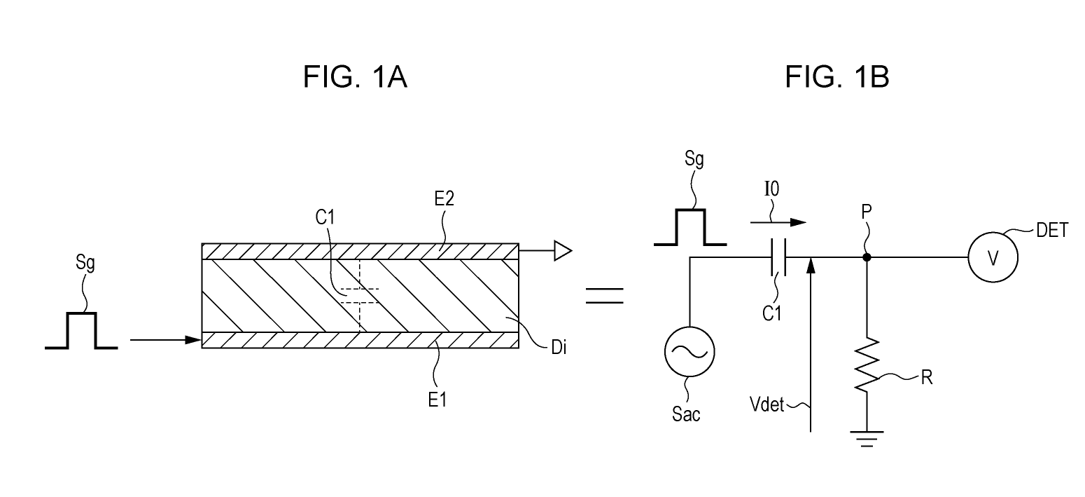

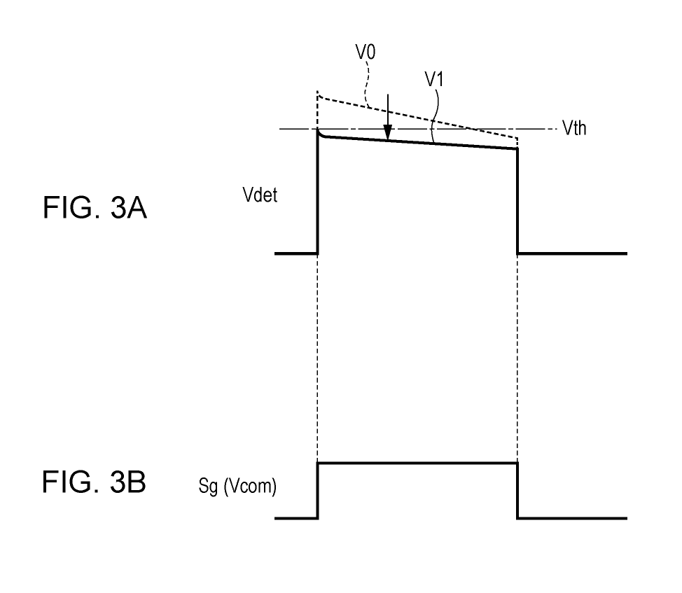

First, with reference to FIG. 1 to FIG. 3, description will be given of the basic principles of the touch detection method in the display apparatus (the display apparatus having a touch sensor attached) according to the embodiments below. The touch detection method is realized as an electrostatic capacitance type touch sensor, for example, as shown in FIG. 1A, configured by a capacitive element using a pair of electrodes (driving electrode E1 and detection electrode E2) arranged facing each other and interposed with a dielectric Di. This structure is represented as an equivalent circuit shown in FIG. 1B. The capacitive element C1 is configured by the driving electrode E1, detection electrode E2 and dielectric Di. The capacitive element C1 has one edge thereof connected to an AC signal source (driving signal source) Sac; the other edge P is grounded through a resistor R and connected to a voltage detector (detection circuit) DET. When an AC rectangular wave Sg (FIG. 3B) of a predetermined frequency (for example, approximately several kHz to up to 19 kHz) is applied to the driving electrode E1 (one edge of the capacitive element C1) from the AC signal source Sac, an output waveform (detection signal Vdet) as shown in FIG. 3A appears at the detection electrode E2 (other edge P of the capacitive element C1). In addition, the AC rectangular wave Sg corresponds to the common driving signal Vcom to be described later.

In a state of not contacting (or being in proximity to) a finger, as shown in FIG. 1, along with the charging and discharging with respect to the capacitive element C1, the current I0 flows according to the capacitance value of the capacitive element C1. The potential waveform of the other edge P of the capacitive element C1 at this time is, for example, like the waveform V0 of FIG. 3A, and is detected by the voltage detector DET.

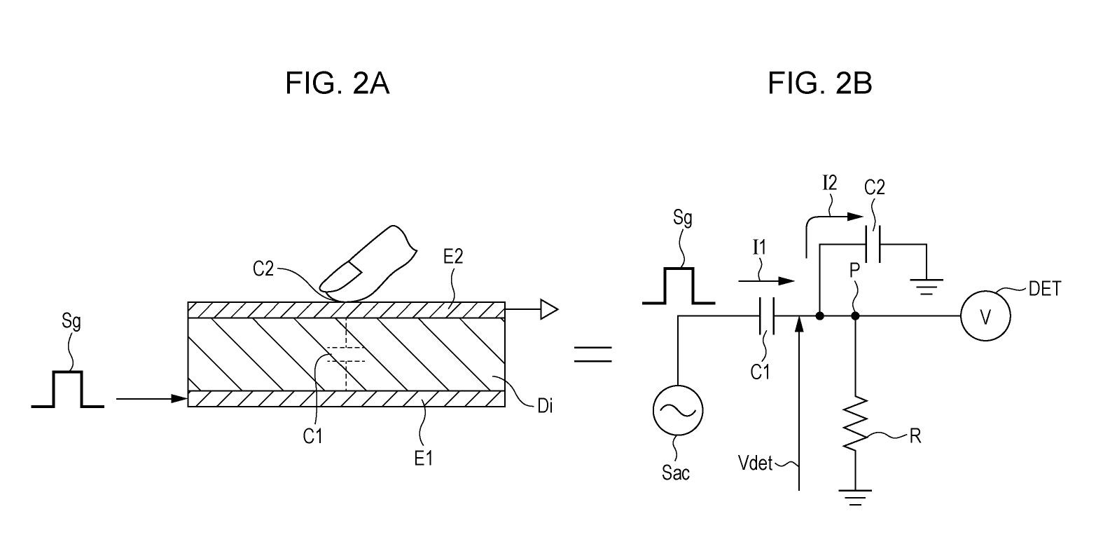

On the other hand, in a state of contacting (or being in proximity to) a finger, as shown in FIG. 2, the capacitive element C2 formed according to the finger is formed to be added in series to the capacitive element C1. In such a state, along with the charging and discharging with respect to the capacitive elements C1 and C2, the respective currents I1 and I2 flow. The potential waveform of the other edge P of the capacitive element C1 at this time is, for example, like the waveform V1 of FIG. 3A, and is detected by the voltage detector DET. At this time, the potential of the point P becomes a voltage dividing potential determined by the values of the currents I1 and I2 flowing in the capacitive elements C1 and C2. For this reason, the waveform V1 has a value smaller than the waveform V0 in a non-contact state. The voltage detector DET, as will be described later, compares a detected voltage with a predetermined threshold value voltage Vth and determines a non-contact state when the detected voltage is the threshold value voltage or more and determines a contact state when the detected voltage is less than the threshold value voltage. In this manner, touch detection becomes possible.

### Embodiments

### Configuration of Display Apparatus 1

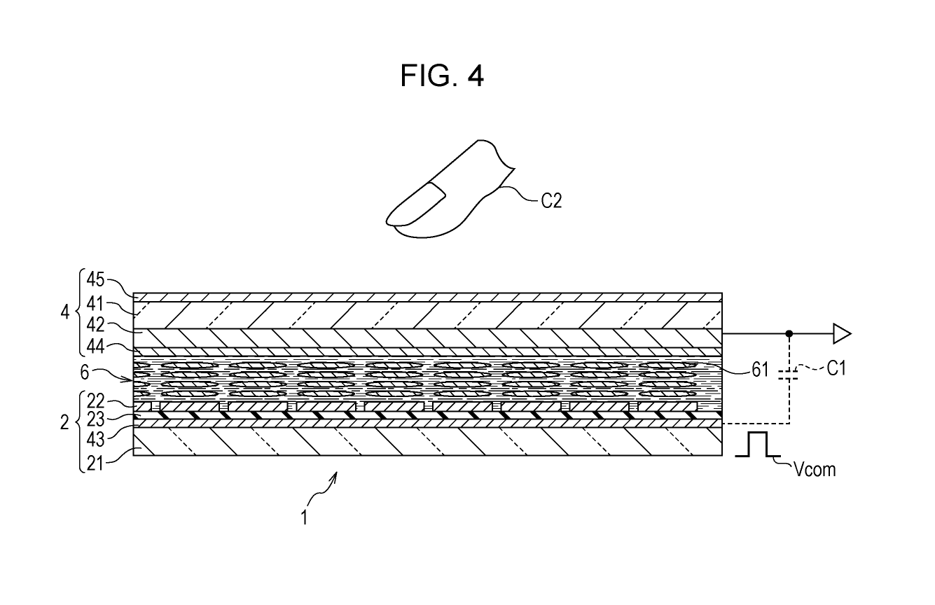

FIG. 4 represents the cross-sectional structure of main parts of a display apparatus (display apparatus 1 having a touch sensor attached) provided with the semiconductor device (semiconductor circuit portion) according to an embodiment of the present disclosure. The display apparatus 1 uses a liquid crystal element as a display element and configures an electrostatic capacitance type touch sensor using both a part of the electrode originally provided in the liquid crystal element (the common electrode 43 to be described later) and a driving signal for display (the driving signal Vcom to be described later). That is, the display apparatus 1 has a display function and a touch sensor function.

As shown in FIG. 4, the display apparatus 1 is provided with a pixel substrate 2, an opposing substrate 4 arranged to face the pixel substrate 2, and a liquid crystal layer 6 interposed between the pixel substrate 2 and the opposing substrate 4.

The pixel substrate 2 has a TFT substrate 21 as a circuit substrate, a common electrode/sensor driving electrode 43 formed on the TFT substrate 21, and a plurality of pixel electrodes 22 disposed in matrix form through the insulating layer 23 on the common electrode/sensor driving electrode 43. On the TFT substrate 21, other than a display driver (not shown) for driving each pixel electrode 22 and the TFT (thin film transistor), there is formed wiring such as a signal line (data line 25 to be described later) supplying an image signal to each pixel electrode 22 and a gate line (gate line 26 to be described later) driving each TFT. In addition, a detection circuit performing a touch detection operation to be described later may be further formed on the TFT substrate 21.

The common electrode/sensor driving electrode 43 (below, simply referred to as the “common electrode 43”) is a common electrode common to each display pixel and is also used as a sensor driving electrode configuring a part of a touch sensor performing a touch detection operation. The common electrode/sensor driving electrode 43 corresponds to the driving electrode E1 in FIG. 1. That is, the common driving signal Vcom of the AC rectangular wave is set to be applied to the common electrode 43. The common driving signal Vcom delimits the pixel voltage applied to the pixel electrode 22 and the display voltage of each display pixel; however, the common driving signal Vcom is also used as the driving signal of the touch sensor. The common driving signal Vcom corresponds to the AC rectangular wave Sg supplied from the driving signal line Sac of FIG. 1. In other words, the common driving signal Vcom reverses the polarity for each predetermined period.

The opposing substrate 4 has a glass substrate 41, a color filter 42 formed on one surface of the glass substrate 41, and a sensor detection electrode (touch detection electrode) 44 formed on the color filter 42. In addition, a polarizing plate 45 is disposed on the other surface of the glass substrate 41.

The color filter 42 has a configuration in which color filter layers of three colors of red (R), green (G), and blue (B) are periodically arranged and the three colors of R, G, and B are associated as a group to correspond to each display pixel (pixel electrode 22). The sensor detection electrode 44 is configured as a part of a touch sensor and corresponds to the detection electrode E2 in FIG. 1.

The liquid crystal layer 6 modulates the light passing therethrough according to the state of the electric field, and, for example, liquid crystal of various modes such as TN (Twisted Nematic), VA (Vertical Alignment), and ECB (Electrically Controlled Birefringence) are used. Alternatively, a liquid crystal of a transverse electric field mode such as an FFS (Fringe Field Switching) mode or an IPS (In-Plane Switching) may be used.

Here, between the liquid crystal layer 6 and the pixel substrate 2 and between the liquid crystal layer 6 and the opposing substrate 4, oriented films are respectively disposed. Further, an incident side polarizing plate is arranged on the lower surface side of the pixel substrate 2; however, this is omitted from the drawings here.

### (Detailed Configuration Example of Common Electrode 43 and Sensor Detection Electrode 44)

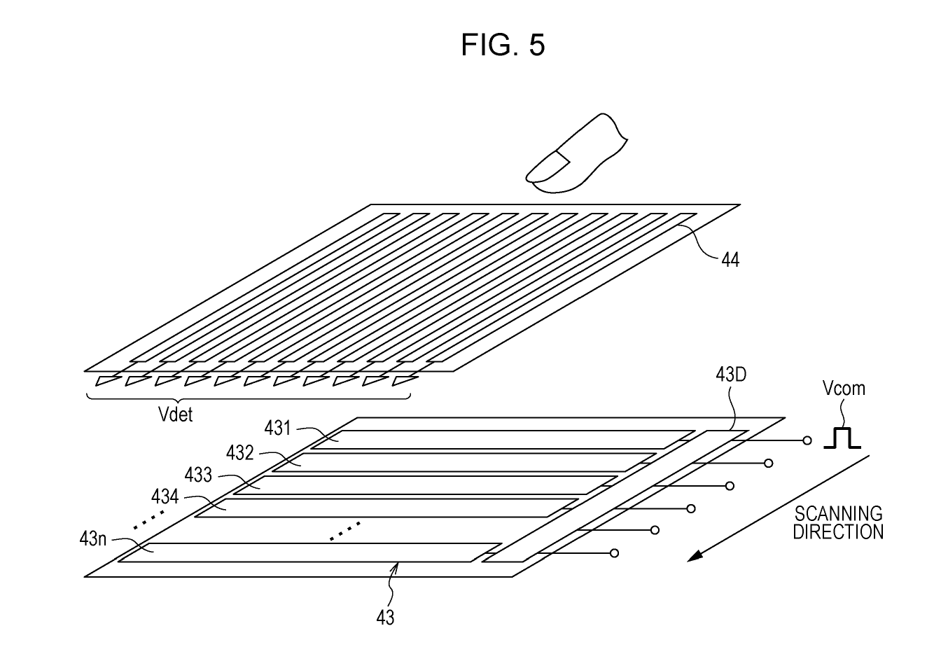

FIG. 5 represents a configuration example of the common electrode 43 and the sensor detection electrode 44 in a perspective state. In this example, the common electrode 43 is divided into electrode patterns of a plurality of stripe shapes (here, as an example, formed of n (n is an integer of 2 or more) common electrodes 431 to 43n) extending in the left and right direction of the drawing. The common driving signal Vcom according to the common electrode driver 43D is supplied in order to each electrode pattern, whereby the line sequential scan driving is performed in a time divided manner as will be described later. On the other hand, the sensor detection electrode 44 is configured from a plurality of stripe shaped electrode patterns extending in a perpendicular direction to the direction in which the electrode pattern of the common electrode 43 extends. From each electrode pattern of the sensor detection electrode 44, a detection signal Vdet is respectively output so as to be input to a detection circuit 8 to be described later.

### (Example of Pixel Structure and Driver Configuration)

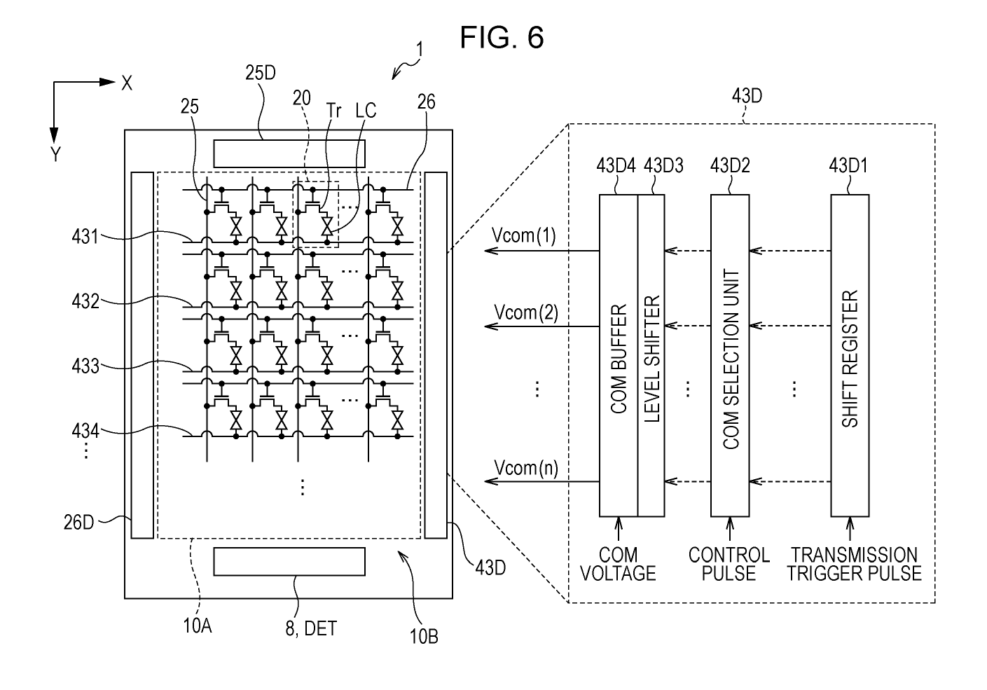

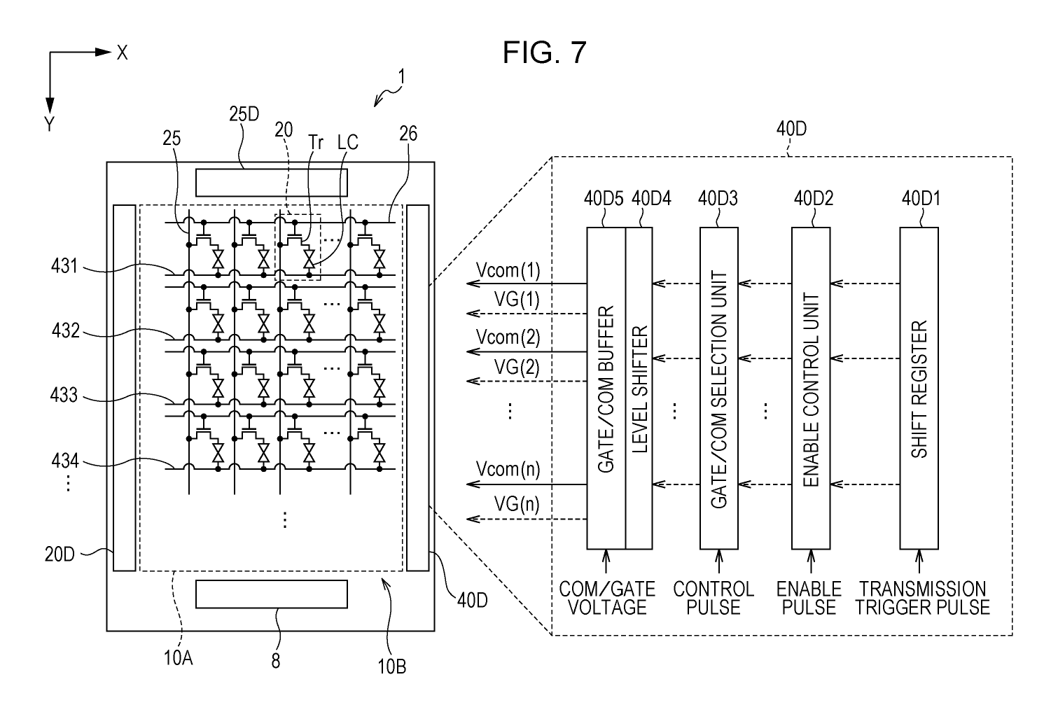

FIG. 6 and FIG. 7 represent examples of the pixel structure and configuration of various types of drivers in the display apparatus 1. In the display apparatus 1, a plurality of display pixels 20 (pixels) having a TFT element Tr and a liquid crystal element LC is arranged in a matrix form in the effective display region 10A. That is, a display unit having a plurality of display pixels 20 is disposed in the effective display region 10A. A pixel circuit including a TFT element Tr is formed in each display pixel 20. In addition, a peripheral circuit (display driver and detection circuit 8 (DET)) including a semiconductor device (semiconductor circuit unit) to be described later is disposed in the frame region 10B (non-display region) positioned at the outer edge (outer circumference) of the effective display region 10A. Here, in FIG. 6 and FIG. 7, the X axis direction corresponds to a horizontal line direction (H direction, second direction) and the Y axis direction corresponds to a vertical line direction (V direction, first direction). The same applies to the other drawings below.

In the example shown in FIG. 6, a gate driver 26D as a display driver (scan line driving circuit), a common electrode driver 43D and a data driver 25D (signal line driving circuit), as well as a detection circuit 8 are disposed in the frame region 10B. The gate driver 26D is a circuit which sequentially drives the plurality of display pixels 20 along the vertical line direction (Y axis direction, first direction). The data driver 25D is a circuit supplying a video signal with respect to the display pixels 20 to be driven. Here, the gate driver 26D, the common electrode driver 43D, the data driver 25D, and the detection circuit 8 correspond to one specific example of a “peripheral circuit” in the present disclosure.

In the display pixels 20, a gate line 26 connected to the gate driver 26D, a signal line (data line) 25 connected to the data driver 25D, and common electrodes 431 to 43n connected to the common electrode driver 43D are connected. As described above, the common electrode driver 43D sequentially supplies common driving signals Vcom (Vcom (1) to Vcom (n)) with respect to the common electrodes 431 to 43n. The common electrode driver 43D has, for example, a shift register 43D1, a COM select unit 43D2, a level shifter 43D3, and a COM buffer 43D4.

The shift register 43D1 is a logic circuit for sequentially transferring an input pulse. Specifically, by entering the transfer trigger pulse (start pulse) with respect to the shift register 43D1, clock transfer is started. Further, when a start pulse is input a plurality of times within one frame period, it is possible to repeat the transfer at each time. In addition, as the shift register 43D1, respective independent transfer logic circuits may be set in order to control the plurality of common electrodes 431 to 43n respectively. However, in such a case, since the scale of the control circuit becomes large, as shown in FIG. 7 to be described later, the transfer logic circuit is preferably set to be commonly used by the gate driver and the common electrode driver, and further, is preferably a single circuit regardless of the number of common electrodes 43.

The COM select unit 43D2 is a logic circuit controlling whether or not the common driving signal Vcom is output with respect to each display pixel 20 in the effective display region 10A. That is, the output of the common driving signal Vcom is controlled according to the position and the like in the effective display region 10A. In addition, by varying the control pulse to be input with respect to the COM select unit 43D2, for example, it is possible to arbitrarily move the output position of the common driving signal Vcom at each horizontal line, or move the output position after a plurality of horizontal intervals.

The level shifter 43D3 is a circuit for shifting a control signal supplied from the COM select unit 43D2 to a potential level sufficient to control the common driving signal Vcom.

The COM buffer 43D4 is a final output logic circuit for sequentially supplying the common driving signal Vcom (Vcom (1) to Vcom (n)) and is configured to include a buffer circuit and the like. In addition, in the COM buffer 43D4, a predetermined COM voltage used when the common driving signal Vcom is generated is set to be supplied.

On the other hand, in the example shown in FIG. 7, a T/G and DC/DC converter 20D as a display driver, a gate and common electrode driver 40D and a data driver 25D, as well as a detection circuit 8 are disposed in the frame region 10B. The T/G and DC/DC converter 20D fulfils a role as a T/G (timing generator) and a DC/DC converter. The gate and common electrode driver 40D supplies gate driving signals with respect to each display pixel 20 through the gate line 26 and sequentially supplies common driving signals Vcom (Vcom (1) to Vcom (n)) with respect to the common electrodes 431 to 43n. Here, the gate and common electrode driver 40D, the data driver 25D, and the detection circuit 8 correspond to one specific example of a “peripheral circuit” in the present disclosure.

In the display pixels 20, a gate line 26 connected to the gate and common electrode driver 40D and common electrodes 431 to 43n are connected to data lines 25 connected to the data driver 25D. The gate and common electrode driver 40D has, for example, a shift register 40D1, an enable control unit 40D2, a gate/COM select unit 40D3, a level shifter 40D4, and a gate/COM buffer 40D5.

Other than the gate driver and the common electrode driver used together, the shift register 40D1 has the same function as the shift register 43D1 described above.

The enable control unit 40D2 generates a pulse for controlling the gate line 26 by using a clock pulse transferred from the shift register 40D1 and taking in an enable pulse.

The gate/COM select unit 40D3 is a logic circuit controlling whether or not the common driving signal Vcom and the gate signal VG are output with respect to each display pixel 20 in the effective display region 10A. That is, the output of the common driving signal Vcom and the gate signal VG are respectively controlled according to the position and the like in the effective display region 10A.

The level shifter 40D4 is a circuit for shifting a control signal supplied from the gate/COM select unit 40D3 to a potential level sufficient to control the gate signal VG and the common driving signal Vcom respectively.

The gate/COM buffer 40D5 is a final output logic circuit for sequentially supplying the common driving signal Vcom (Vcom (1) to Vcom (n)) and the gate signal VG (VG (1) to VG (n)) and is configured to include a buffer circuit and the like. In addition, in the gate/COM buffer 40D5, a predetermined COM/gate voltage used when the common driving signal Vcom and the gate voltage VG are generated is set to be supplied.

### (Circuit Configuration Example of the Detection Circuit 8)

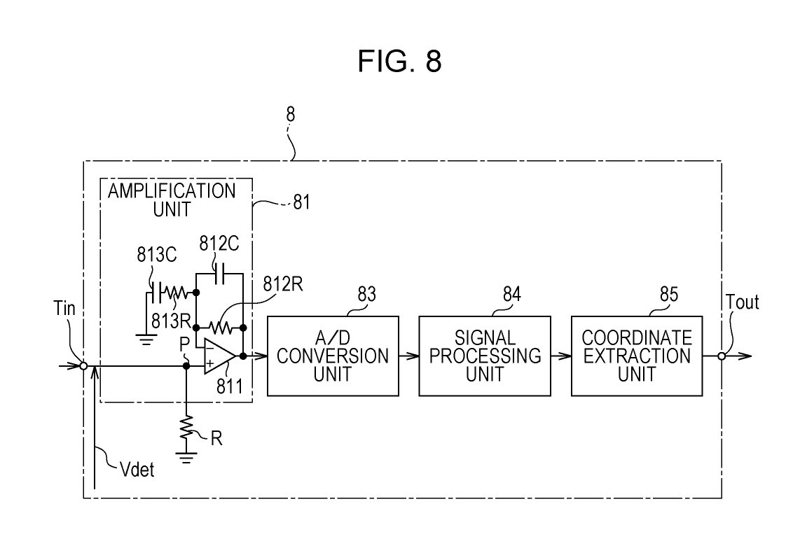

FIG. 8 represents a circuit configuration example of the detection circuit 8 shown in FIG. 6 and FIG. 7. The detection circuit 8 (voltage detector DET) has an amplification unit 81, an A/D (analog/digital) conversion unit 83, a signal processing unit 84, a coordinate extraction unit 85 and a resistor R.

The amplification unit 81 is a member amplifying a detection signal Vdet input from the input terminal Tin and has an operational amplifier for signal amplification 811, two resistors 812R and 813R, and two capacitors 812C and 813C. The positive input terminal of the operational amplifier 811 (+) is connected to the input terminal Tin, the output terminal is connected to the input terminal of an A/D conversion unit 83 to be described later. One terminal of the resistor 812R and the capacitor 812C is connected to the output terminal of the operational amplifier 811, and the other terminal of the resistor 812R and the capacitor 812C is connected to a negative input terminal (−) of the operational amplifier 811. Further, one terminal of the resistor 813R is connected to the other terminal of the resistor 812R and the capacitor 812C, and the other terminal of the resistor 813R is connected to the ground via the capacitor 813R. In this manner, the resistor 812R and the capacitor 812C function as a low pass filter (LPF) cutting out the high frequency and allowing the low frequency to pass, in addition, the resistor 813R and the capacitor 813C function as a high pass filter (HPF) allowing the high frequency to pass.

The resistor R is arranged between the connection point P of the positive input terminal (+) side of the operational amplifier 811 and the ground. The resistor R is to prevent the sensor detection electrode 44 from entering a floating state and preserve a stable state. In this manner, in the detection circuit 8, the signal value of the detection signal Vdet is prevented from fluctuating and changing and, furthermore, there is an advantage in that static electricity may escape to the ground through the resistor R.

The A/D conversion unit 83 is a member converting the analog detection signal Vdet amplified in the amplifier 81 to a digital detection signal and is configured to include a comparator (not shown). The comparator compares the potential of the input detection signal and the threshold value voltage Vth (refer to FIG. 3).

The signal processing unit 84 performs a predetermined signal process with respect to the digital detection signal output from the A/D conversion unit 83 (for example, a signal process such as a digital noise removal process or a process converting frequency information into position information).

The coordinate extraction unit 85 calculates the detection result based on the detection signal output from the signal processing unit 84 and performs output thereof to the output terminal Tout. The detection result includes whether or not touch has occurred and, if so, the position coordinates of such a portion.

### (Cross-Sectional Configuration Example of Pixel Substrate 2)

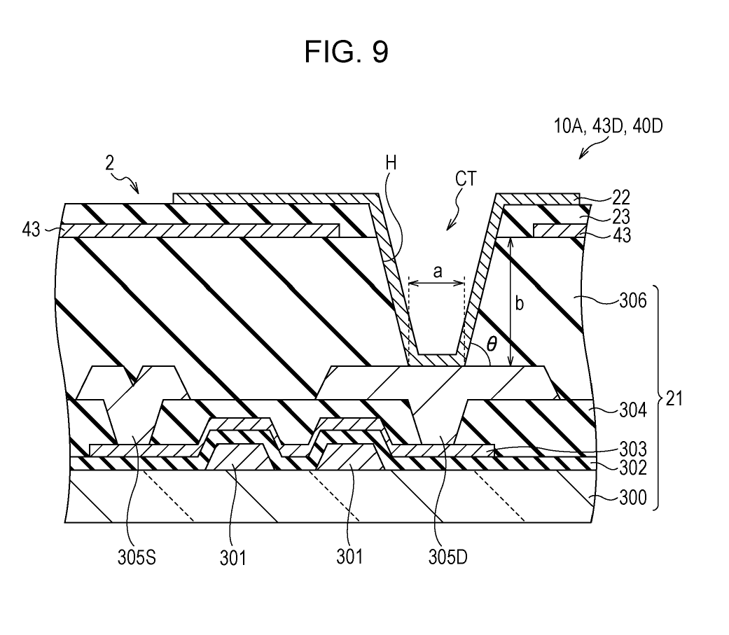

Here, with reference to FIG. 9 to FIG. 12, description will be given of a cross-sectional configuration example of the effective display region 10A in the above-described pixel substrate 2 and at the peripheral circuit. FIG. 9 represents a cross-sectional configuration example of the effective display region 10A in the pixel substrate 2 and the peripheral circuit (here, as an example, a common electrode driver 43D or a gate and common electrode driver 40D) in the pixel substrate 2.

In the cross-sectional configuration example shown in FIG. 9, a gate electrode 301, a gate insulating film 302, a semiconductor layer 303, an interlayer insulating film 304, a source electrode 305S and a drain electrode 305D (first electric conductor), as well as a planarizing film 306 (insulating layer) are laminated in this order on the substrate 300. In addition, in the cross-sectional configuration example, a common electrode 43 (second electric conductor), an insulating layer 23 and a pixel electrode 22 (second electric conductor) are laminated in this order on the planarizing layer 306.

The substrate 300 is a support substrate in the pixel substrate 2, for example, formed of a glass substrate, a semiconductor substrate or the like.

The gate electrode 301 is formed of, for example, a metal material such as aluminum (Al) or molybdenum (Mo), and, for example, the thickness thereof is approximately 10 to 100 nm. The gate insulating film 302 is formed of, for example, an insulating material such as silicon oxide (SiO₂) or silicon nitride (SiN), and, for example, the thickness thereof is approximately 10 to 100 nm. The semiconductor layer 303 is formed of, for example, various types of semiconductor material such as silicon (Si), oxide semiconductors, or compound semiconductors and, for example, the thickness thereof is approximately 10 to 100 nm. The interlayer insulating film 304 is formed of, for example, an insulating material such as SiO₂ or SiN, and the thickness thereof is approximately 100 to 1000 nm. The source electrode 305S and the drain electrode 305D are respectively formed of, for example, a metal material such as Al or Mo, and, for example, the thicknesses thereof are approximately 100 to 1500 nm. A thin film transistor (TFT) is formed as a semiconductor element by the gate electrode 301, the gate insulating film 302, the semiconductor layer 303, the interlayer insulating film 304, the drain electrode 305D and the source electrode 305S.

The planarizing film 306 is disposed at an interlayer position between the source electrode 305S and the drain electrode 305D, and the pixel electrode 22, the insulating layer 23 or the common electrode 43, and is a thick film insulating layer. The planarizing film 306 is formed of, for example, organic insulating material (resin material), and, for example, the thickness thereof is approximately 0.5 to 10 μm. In particular, the thickness of the planarizing film 306 is at least, for example, preferably 3 μm or more in the vicinity of the forming region of the contact portion CT to be described below. This is because, in this manner, as described above, the signal line capacitance is reduced, and a reduction of power consumption and an improvement in the image quality are achieved.

In the planarizing film 306, a through hole (contact hole) H is formed. Here, in the interior of the through hole H, a contact portion CT electrically connecting the drain electrode 305D and the pixel electrode 22 or the common electrode 43 is formed. The contact portion CT (here, a configuration portion of the contact portion CT in the pixel electrode 22) is formed so as to imitate (cover) the inner surface shape (wall surface shape and bottom surface shape) of the through hole H. In other words, the contact portion CT is formed using the sputtering method or the like as described below rather than by CMP (Chemical Mechanical Polishing) or the like. For example, the through hole H has a rectangular columnar shape, a cylindrical shape (elliptic cylinder shape) or the like in which the inner radius a=approximately 6 μm or less in, for instance, the bottom surface in the effective display region 10A. In addition, for example, the peripheral circuit has a rectangular columnar shape, a cylindrical shape (elliptic cylinder shape) or the like in which the inner radius a=approximately 10 μm or less in, for instance, the bottom surface.

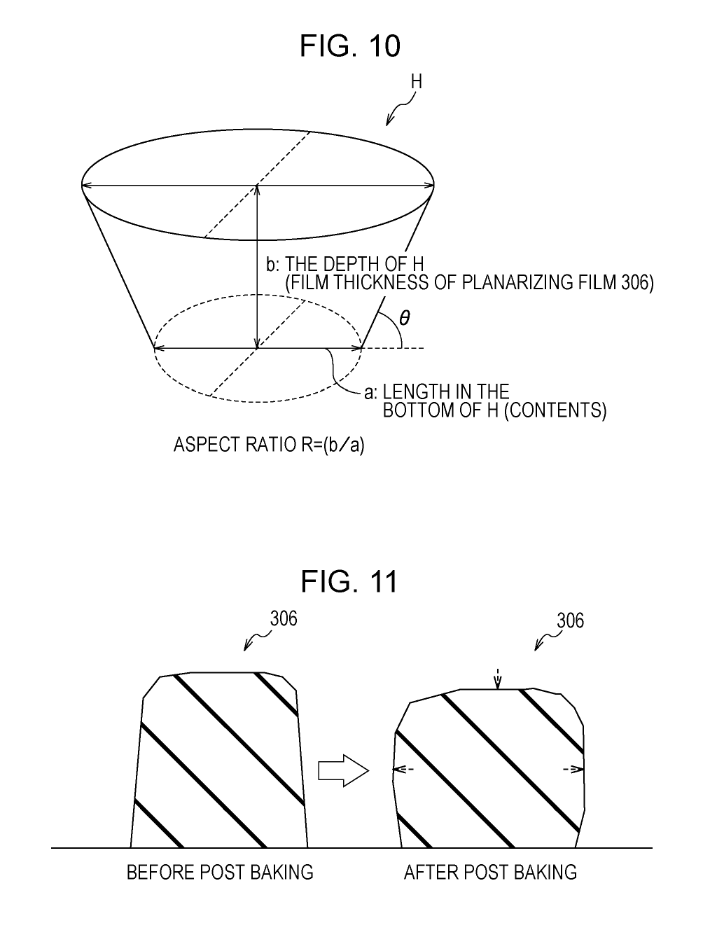

As shown in FIG. 9 and FIG. 10, the through hole H, when the inner radius in the bottom surface is a and the depth (with respect to the film thickness of the planarizing film 306) is b, the aspect ratio R thereof (=b/a) becomes high to a certain extent (for example, as will be described below, R≧0.42 approximately). In addition, the tapered angle θ (angle made by the bottom surface of the through hole H (surface of the drain electrode 305) and the wall surface) of the through hole H is an acute angle (0°<θ<90°). The tapered angle θ is preferably 75° or less (0°<θ≦75°), particularly in the effective display region 10A. Regarding the electrical connection between the drain electrode 305D and the pixel electrode 22, considering the display brightness changes due to variations of the connection resistance (contact resistance), it is particularly important to have a reliable (good) electrical connection.

Here, such a contact portion CT may be formed, for example, in the following manner. That is, first, the gate electrode 301, the gate insulating film 302, the semiconductor layer 303 and the interlayer insulating film 304 formed of the materials described above are respectively formed in this order on the substrate 300 using techniques such as photolithography. Next, on the interlayer insulating film 304, the source electrode 305S and the drain electrode 305D formed of the materials described above are, for example, formed by a photolithography technique using a sputtering method. Subsequently, on the source electrode 305S and the drain electrode 305D, a thick film planarizing film 306 formed of the material described above is, for example, formed by a photolithography technique using a CVD (Chemical Vapor Deposition) method, a vapor deposition method or the like.

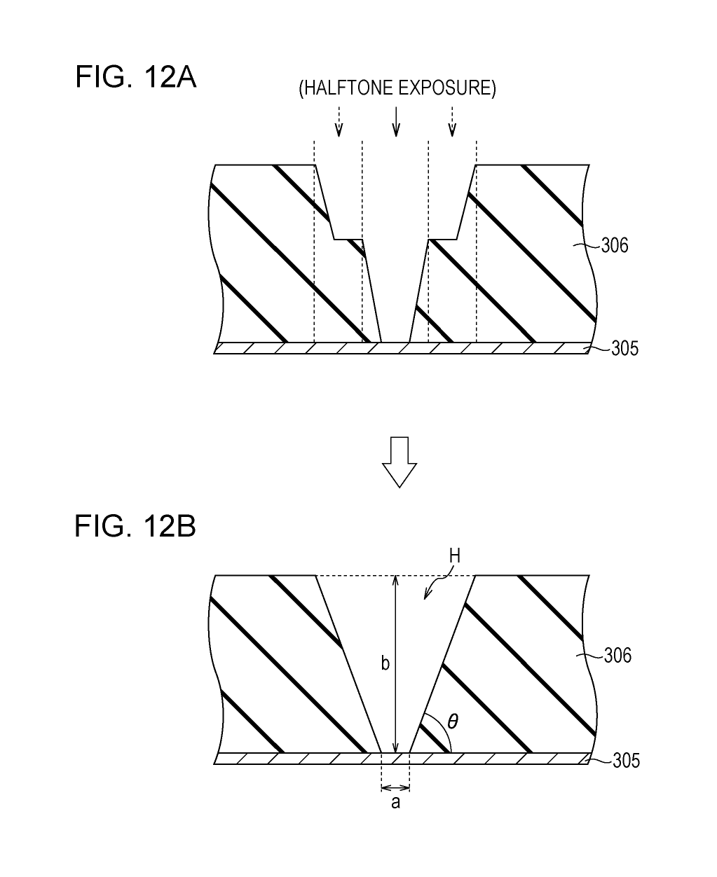

After that, a through hole H having the above-described tapered angle θ (0°<θ<90°) with respect to the planarizing film 306 is formed using a photolithography technique. During the forming of the through hole H, for example, as schematically shown in FIG. 11, it is possible perform the forming using the reflow phenomenon of the planarizing film 306 (resin film) using the heat at the time of the post-baking process. Specifically, as shown in FIG. 12A, for example, first, during the exposure process before the post-baking process, halftone exposure is performed in the vicinity of the forming region of the through hole H, and a step-shaped through hole is formed. Next, by performing the post bake process (high temperature firing of about 200° C.), the reflow phenomenon of the planarizing film 306 described above is generated, and, as a result, the through hole H shown in FIG. 12B is formed. In this manner, even in a through hole H in which the aspect ratio R is high to a certain extent, it is possible to obtain good coverage. Here, in addition to the technique using such halftone exposure, it is possible to form the through hole H having a tapered angle θ (0°<θ<90°) by using a material (material with high reflowability) in which the Tg (glass transition point) is low as the planarizing film 306. As methods to lower the Tg of the planarizing film 306, there are techniques such as lowering the average molecular weight, reducing the parts contributing to cross-linking, raising the decomposition temperature of the parts to contribute to the cross-linking reaction, and decreasing the cross-linked points, and it is possible to adjust the Tg using one or a combination thereof.

Then, on the planarizing film 306, a common electrode 43 and an insulating layer 23 are formed in this order, and the pixel electrode 22 is formed using a sputtering method so as to imitate the inner surface shape of the through hole H. In this manner, the drain electrode 305D and the pixel electrode 22 or the common electrode 43 are electrically connected, and the contact portion CT shown in FIG. 9 is formed.

### [Action and Effect of Display Apparatus 1]

### 1. Basic Operation

In the display apparatus 1, the display driver of the pixel substrate 2 (common electrode driver 43D or the like) supplies a common driving signal Vcom with respect to each electrode pattern of the common electrode 43 (common electrode 431 to 43n) in line sequential order. The display driver also supplies a pixel signal (image signal) to the pixel electrode 22 through the signal line 25 and, furthermore, in synchronization therewith, controls the switching of the TFT (TFT element Tr) of each pixel electrode through the gate line 26 in line sequence. In this manner, in the liquid crystal layer 6, an electric field of the length direction (vertical direction with respect to the substrate) determined by the common driving signal Vcom and each image signal is applied to each display pixel 20 and modulation of the liquid crystal state is performed.

Meanwhile, at the side of the corresponding substrate 4, a capacitive element C1 is formed at the intersection portion of each electrode pattern of the common electrode 43 and each electrode pattern of the sensor detection electrode 44. Here, for example, when the common driving signal Vcom is sequentially applied in a time divided manner to each electrode pattern of the common electrode 43 as shown by an arrow (scanning direction) in FIG. 5, the following occurs. That is, with respect to each individual capacitive element C1 of one column portion formed at the intersection portion of electrode patterns of the common electrode 43 and electrode patterns of the sensor detection electrode 44 to which the signal is applied, charging and discharging is performed. As a result, the detection signal Vdet of a size according to the capacitance value of the capacitive element C1 is output from each electrode pattern of the sensor detection electrode 44. In a state in which the surface of the corresponding substrate 4 is not touched by the user's finger, the size of the detection signal Vdet is almost constant. Along with the scan of the common driving signal Vcom, the column of the capacitive elements C1 which is the target of charging and discharging is moved in a line sequential manner.

Here, when the surface of the corresponding substrate 4 is touched by the user's finger at any place, a capacitive element C2 is added by the finger to the capacitive element C1 originally formed at the touched places. As a result, the value of the driving signal Vdet of the time point when the touched places are scanned (that is, when the common driving signal Vcom is applied to the electrode patterns corresponding to the touched places in the electrode patterns of the common electrode 43) is smaller than the other places. The detection circuit 8 compares the detection signal Vdet with the threshold value voltage Vth, and, when the detection signal Vdet is less than the threshold value voltage Vth, determines that place as a touched place. The touched place may be estimated from the application timing of the common driving signal Vcom and the detection timing of the detection signal Vdet less than the threshold value voltage Vth.

In this manner, in the display apparatus 1 having a touch sensor, the common electrodes 43 originally provided at the liquid crystal display element are also used as one side in a pair of electrodes for touch sensors formed of a driving electrode and a detection electrode. In addition, the common driving signal Vcom as the driving signal for display is also used as the driving signal for the touch sensors. In this manner, in an electrostatic capacitance type touch sensor, it is sufficiently if the newly provided electrodes are only sensor detection electrodes 44 and a driving signal for a touch sensor may not be newly prepared. Accordingly, the configuration is simple.

In addition, in a typical display apparatus having a touch sensor, the size of the current flowing to the sensor is accurately measured and the touched position is determined by analog calculation based on the measurement results thereof. In contrast, in the display apparatus 1 of the embodiment, since it is sufficient to simply digitally detect the presence or absence of relative change (potential change) of the current according to the presence or absence of touching, it is possible to enhance the detection precision with a simple detection circuit configuration. In addition, electrostatic capacitance is formed between the common electrode 43 originally provided for the application of the common driving signal Vcom and the newly provided sensor detection electrode 44, whereby touch detection is performed using the change of the electrostatic capacitance due to the contact of the finger of the user. For this reason, the present application is applicable to mobile device uses in which the potential of the user is often indeterminate.

Further, since the sensor detection electrode 44 is divided into a plurality of electrode patterns and, along with this, each electrode pattern is driven independently in a time divided manner, it is also possible to detect the touched position.

### 2. Action in Contact Portion CT

Next, description will be given of the action of the contact portion CT in the pixel substrate 2 described above while making comparisons to comparative examples.

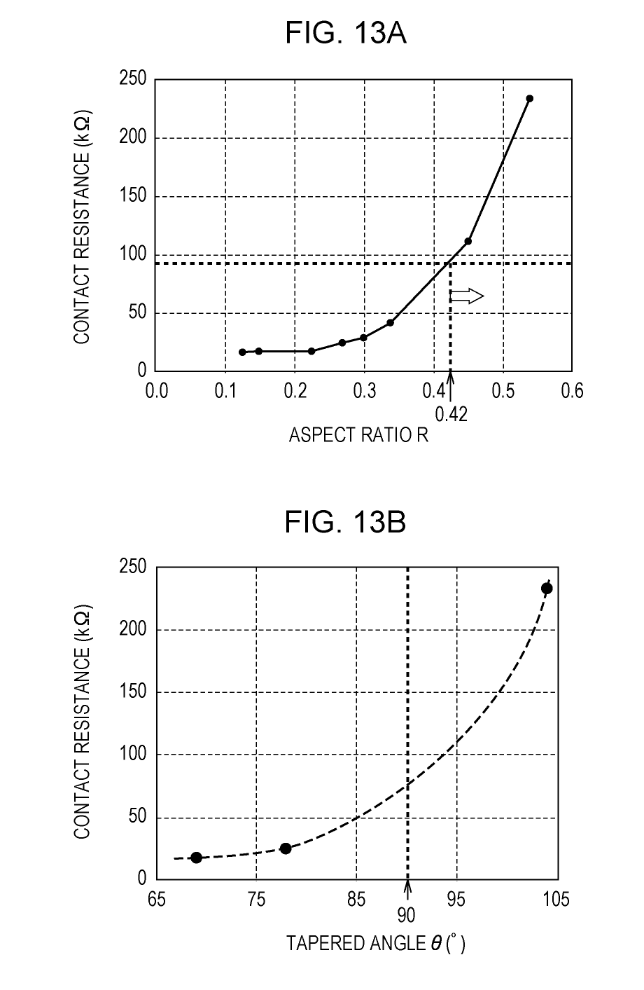

First, in the pixel substrate 2 of the embodiment, since the signal line capacitance is reduced and the time constant is deteriorated, the consumed electric power is reduced and, furthermore, the crosstalk phenomenon at the time of the image display is suppressed and the image quality improved, the planarizing film 306 has a thick film shape. Along with this, since the depth b of the through hole H formed in the planarizing film 306 also becomes larger, as described above, the aspect ratio R (=b/a) of the through hole H is increased to a certain extent. For example, as shown in FIG. 13A, when the aspect ratio R of the through hole H is set to be ≧0.42, the resistance (contact resistance) in the contact portion CT becomes a high resistance value of approximately 90 kΩ or more (conversion value with a sheet resistance of 5 μm×5 μm). In addition, as shown in FIG. 13B, for example, the contact resistance becomes higher as the tapered angle θ increases.

### 2-1 Comparative Example

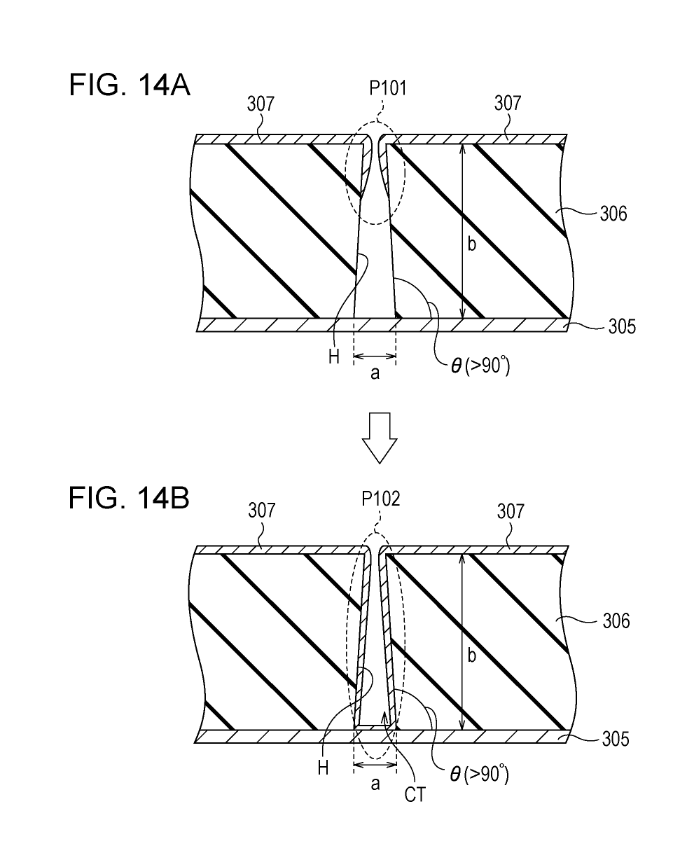

Here, as in the comparative examples shown in FIGS. 14A and 14B, when the tapered angle θ in the through hole H is greater than 90° (θ>90°) and becomes an inverted tapered shape (overhang shape), the following problems occur in the contact portion CT. Specifically, as shown by reference numeral P101 in FIG. 14A, disconnection of the electrode layer 307 (pixel electrode and the like) occurs in the wall surface and the like of the through hole H and, as a result, since the contact portion CT in the through hole H is no longer formed, connection defects (contact defects) occur. Alternatively, for example, as shown by reference numeral P102 in FIG. 14B, the contact portion CT is barely formed, whereby even if the electric connectivity between the drain electrode 305D and the pixel electrode 22 or the common electrode 43 is secured, since the thickness or the like of the electrode layer 307 is insufficient, the contact resistance is increased.

The through hole H of such an inverted tapered shape (overhang shape) is easily generated due to the reflow phenomenon of the planarizing film 306 (resin film) caused by the heat during the post baking process as in FIG. 11 described above. Specifically, when the resin planarizing film 306 shrinks in the post baking process, since the planarizing film 306 is closely attached to the base, the reflowing mainly occurs at a portion above the base side (interface side). Thus, the planarizing film 306 has a thick film shape and, along with this, when the contact area with the base is small, tends to become an overhang shape during the reflow as shown by the broken line arrow in FIG. 11.

In this manner, in the comparative example in which the tapered angle θ in the through hole H becomes larger than 90° (θ>90°), in the contact portion CT (through hole H), disconnections (connection defects) or increases in resistance values (contact resistance) are easily generated. As a result, in the comparative example, since the electric connectivity in the contact portion CT deteriorates and the yield at the time of manufacturing is decreased, the reliability is deteriorated.

### 2-2. Embodiment

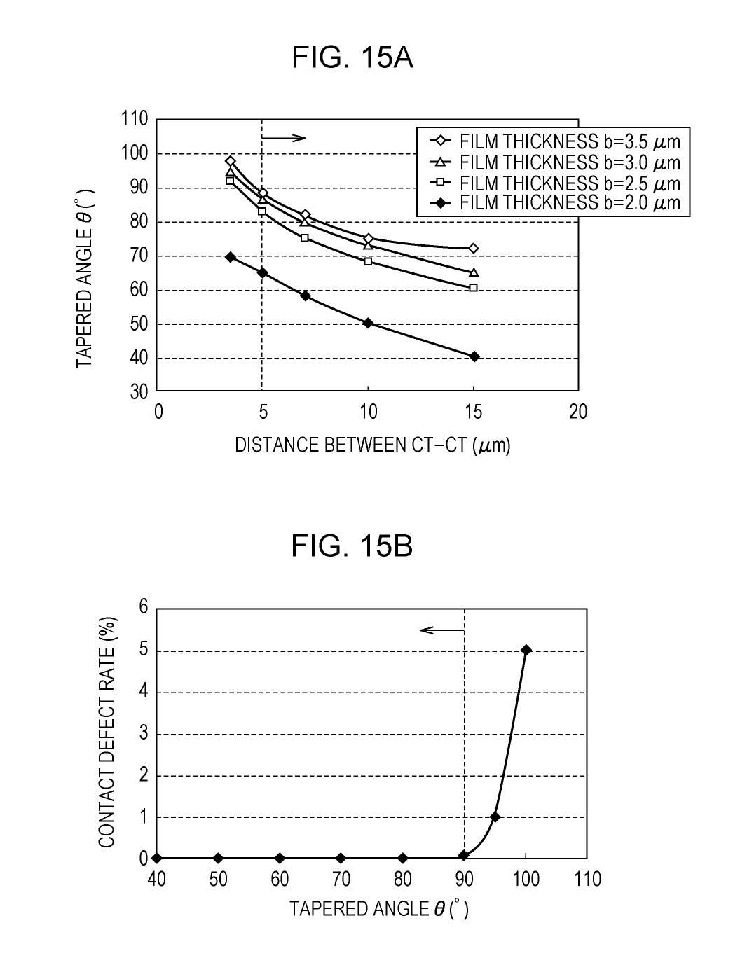

In the corresponding embodiment, as shown in FIGS. 9A and 9B and FIG. 10, a contact portion CT electrically connecting a drain electrode 305 and a pixel electrode 22 or a common electrode 43 is formed so as to imitate the inner surface shape of the through hole H with respect to the planarizing film 306 for which the tapered angle θ is an acute angle (0°<θ<90°). Here, when the film thickness (depth b of the through hole H) of the planarizing film 306 having a thick film shape is, for example, 3.0 μm or more as described above, for instance, as shown in FIG. 15A, to set the tapered angle θ of the through hole H to an acute angle, the distance to the adjoining contact CT may be set to approximately 5 μm or more.

By forming the contact portion CT in this manner, in the embodiment, even if the planarizing film 306 has a thick film shape, the coatability of the through hole H inner surface of the contact portion CT is improved, and a disconnection (connection defect) or increase in resistance value (contact resistance) in the contact portion CT may be suppressed. That is, regardless of the fact that the aspect ratio R is high in the through hole H, the tapered angle θ is a (moderate) acute angle, whereby the contact resistance is suppressed to be low.

In the above present embodiment, since a contact portion CT electrically connecting a drain electrode 305 and a pixel electrode 22 or a common electrode 43 is formed so as to imitate the inner surface shape of the through hole H with respect to the planarizing film 306 for which the tapered angle θ is an acute angle, even if the planarizing film 306 has a thick film shape, it is possible to suppress a disconnection or an increase in the resistance value in the contact portion CT. Accordingly, it is possible to perform electrical connection in the contact portion CT more reliably, and to improve the yield during manufacturing, whereby it is possible to improve reliability. Specifically, as shown in FIG. 15B, for example, since the tapered angle θ becomes an acute angle (0°<θ<90°), it is possible to remarkably reduce the contact defects and to improve the yield (reliability).

Further, since the planarizing film 306 has a thick film shape (for example, the aspect ratio R of the through hole H is set to be ≧0.42), it is possible to reduce the signal line capacitance and deteriorate the time constant, reduce the consumed electric power and, furthermore, suppress the crosstalk phenomenon at the time of the image display and improve the image quality. In particular, when the touch detection operation and the image signal writing operation are performed in one horizontal period, it is possible to obtain an advantageous effect regarding either operation.

In addition, in this embodiment, in relation to the arrangement of columnar spacers (not shown) disposed in the liquid crystal layer 6, the following is true. Specifically, first, in a case where the resin planarizing film 306 is given a thick film shape, when the surface of the display apparatus 1 (liquid crystal panel) is pressed, there is a problem in that the metal layer formed on the planarizing film 306 and the inorganic insulating film are easily cracked in the vicinity of the columnar spacers. This is considered to be caused by the fact that, by making the resin planarizing film 306 having a large amount of elastic deformation in comparison with an inorganic film have a thick film shape, the elastic deformation amount for the applied pressure for the same unit of area becomes large, thereby exceeding the permitted deformation amount of the inorganic film or the like. In the vicinity of the through-hole H, since the shape of the planarizing film 306 is not flat, cracking is easily generated at places where stress concentration has occurred.

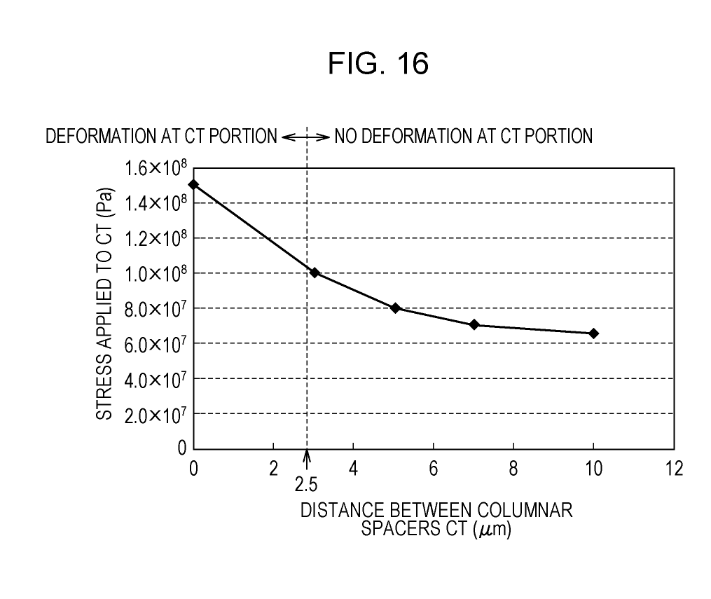

Here, for example, as shown in FIG. 16, by setting the distance between (separating) the columnar spacers and the contact portion CT to be larger than approximately 2.5 μm (about 3 μm), the stress concentration in the vicinity of the through hole H are reduced, whereby the cracking of the inorganic film or the like caused thereby may be reduced. Further, by providing a convex shape on the above-described metal layer or inorganic insulating film and reducing the thickness of the resin planarizing film 306 in the contact portion with the columnar spacers, the elastic deformation amount of the planarizing film 306 is suppressed with the result that cracking of the inorganic film or the like due to pressing of the surface may be improved.

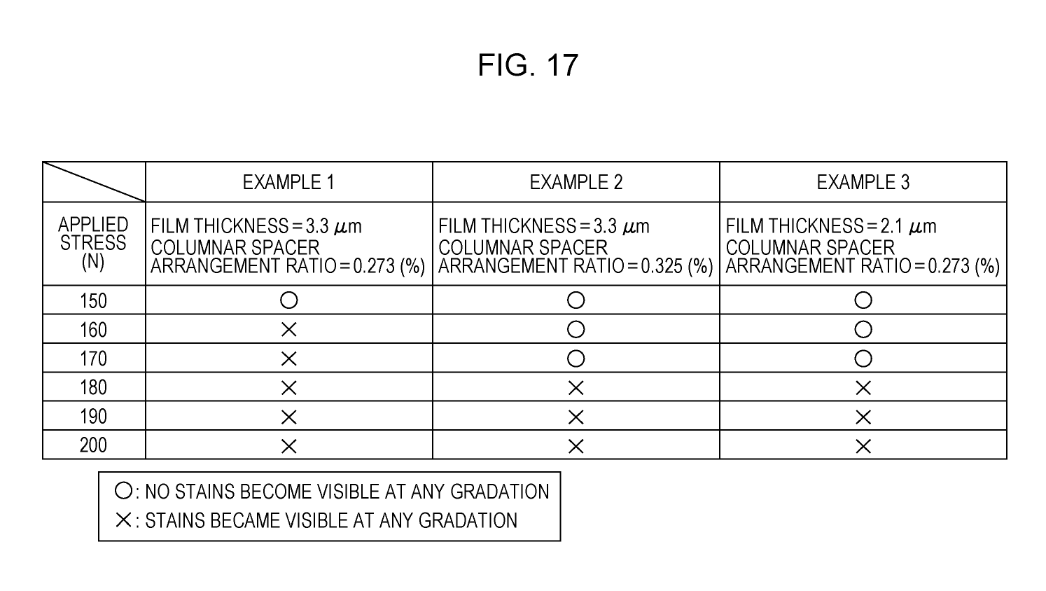

In addition, in a case where the planarizing film 306 is given a thick film shape, in order to preserve the strength for the above-described surface pressing, it is effective to increase the arrangement ratio (arrangement density) of the columnar spacers to a certain extent. Specifically, according to Examples 1 to 3 (results of sensory evaluation experiments of whether or not there were visible stains according to changes in applied stress when the display gradation was changed in the display apparatus 1) as shown in FIG. 17, the following is true. That is, in a case where the film thickness of the planarizing film 306 was 2.1 μm, the arrangement ratio of the columnar spacers is preferably larger than approximately 0.27%.

### APPLICATION EXAMPLES

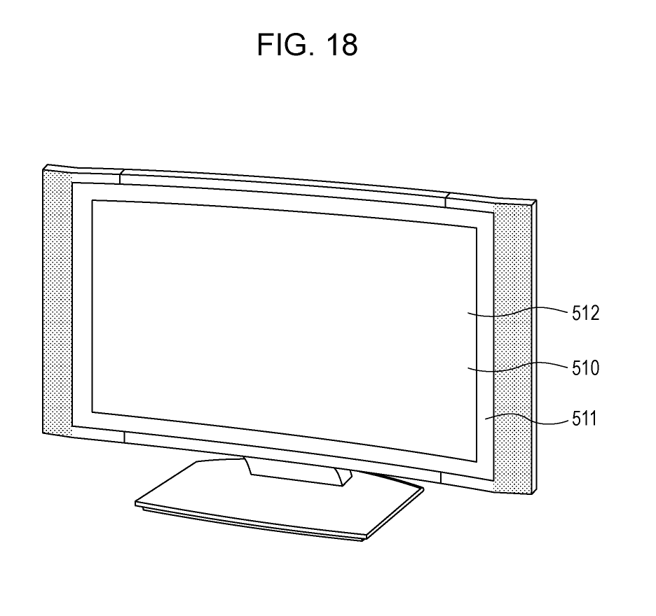

Next, with reference to FIG. 18 to FIG. 22, description will be given of application examples of the display apparatus 1 (the display apparatus having a touch sensor attached) of the above embodiments. The display apparatus 1 may be applied to electronic apparatuses of all fields such as television apparatuses, digital cameras, notebook personal computers, mobile terminal apparatuses such as mobile phones, or video cameras. In other words, the display apparatus 1 may be applied to electronic apparatuses of all fields displaying a video signal input from an external device or a video signal generated internally as an image or as a video.

### Application Example 1

FIG. 18 represents the external appearance of a television apparatus to which the display apparatus 1 is applied. The television apparatus has, for example, an image display screen unit 510 including a front panel 511 and filter glass 512, and the image display screen unit 510 is configured by the display apparatus 1.

### Application Example 2

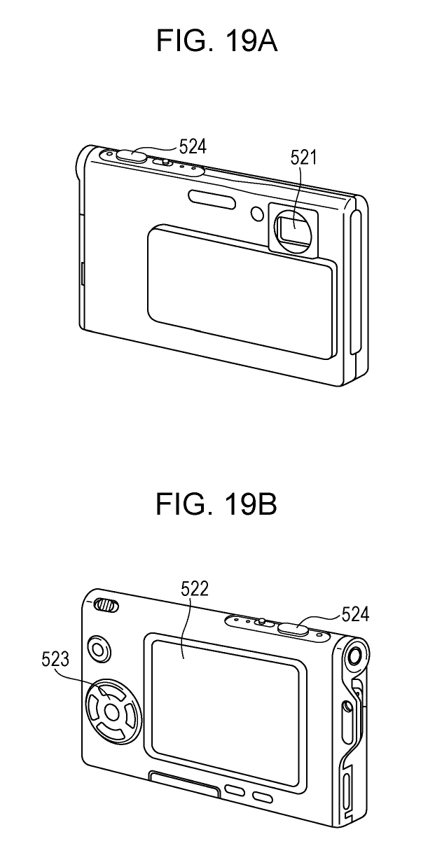

FIGS. 19A and 19B represent the external appearance of a digital camera to which the display apparatus 1 is applied. The digital camera has, for example, a light-emitting unit 521 used for a flash, a display unit 522, a menu switch 523, and a shutter button 524, and the display unit 522 is configured by the display apparatus 1.

### Application Example 3

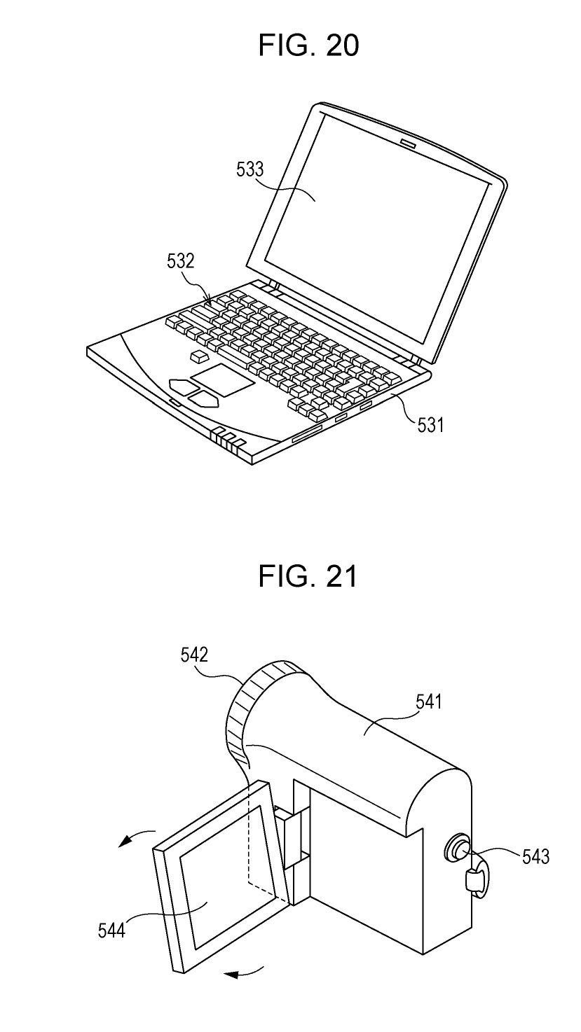

FIG. 20 represents the external appearance of a notebook personal computer to which the display apparatus 1 is applied. This notebook-type personal computer has, for example, a main body 531, a keyboard 532 for input operations of characters or the like, and a display unit 533 displaying images, and the display unit 533 is configured by the display apparatus 1.

### Application Example 4

FIG. 21 represents the external appearance of a video camera to which the display apparatus 1 is applied. The video camera has, for example, a main body unit 541, a lens 542 for imaging a subject provided on a forward side surface of the main body unit 541, an imaging time start/stop switch 543 and a display unit 544. Here, the display unit 544 is configured by the display apparatus 1.

### Application Example 5

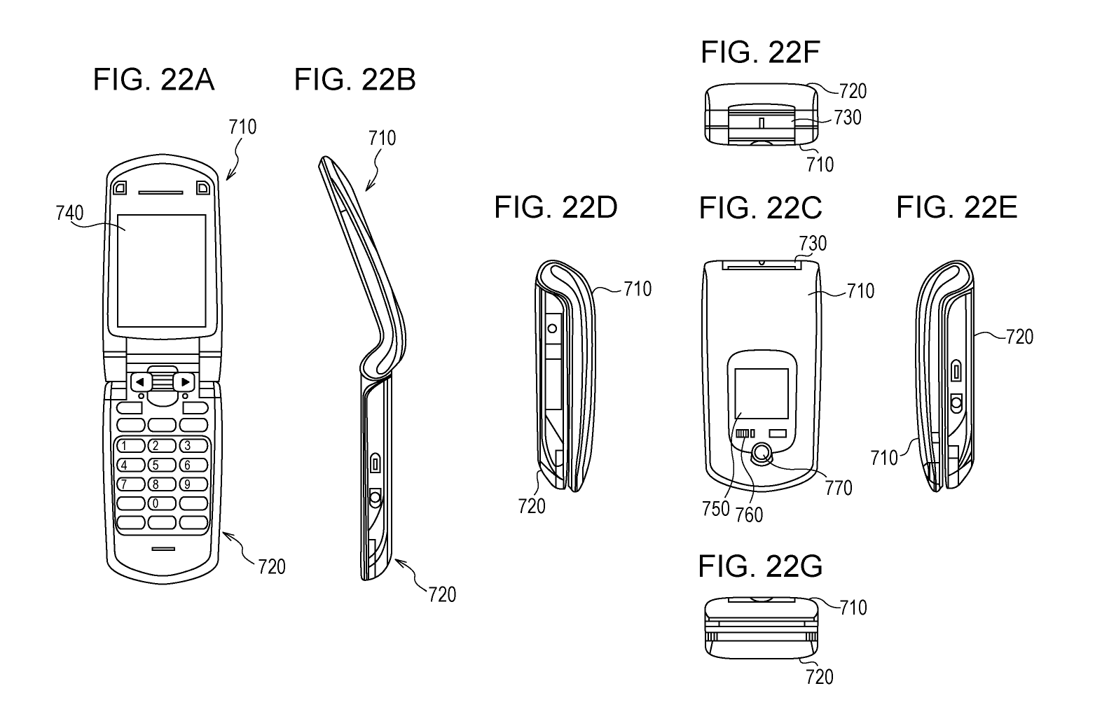

FIG. 22 represents the external appearance of a mobile phone device to which the display apparatus 1 is applied. The mobile phone device is, for example, a device in which an upper housing 710 and a lower housing 720 are linked by a linking portion (hinge portion) 730, and has a display 740, a sub-display 750, a picture light 760 and a camera 770. The display 740 of the sub-display 750 is configured by the display apparatus 1.

### Modification Example

The present technique has been described with reference to embodiments and application examples; however, the present technique is not limited to these embodiments or the like, and various modifications are possible.

For example, the shape and forming position of the contact unit CT are not limited to those described in the above embodiments and the like and, as long as the tapered angle θ of the through hole H is an acute angle, other shapes, forming positions and the like are possible.

In addition, in the above-described embodiments, an electrode of a semiconductor (drain electrode of a thin film transistor) has been described as an example of the “first electric conductor” and, along with this, a pixel electrode and a common electrode have been described as an example of the “second electric conductor”; however, these are not limiting.

In addition, in the above-described embodiments, description has been given of a case where a semiconductor device (semiconductor circuit unit and contact portion) are formed together in an effective display region (pixel circuit) and in a frame region (peripheral circuit); however, these are not limiting. That is, the semiconductor device (semiconductor circuit unit and contact portion) may be set to be disposed in at least one region of an effective display region (pixel circuit) and a frame region (peripheral circuit).

In addition, in the above-described embodiments, description has been given of a display apparatus having a touch sensor attached (display apparatus having a touch sensor function) as an example of the display apparatus; however, without being limited thereto, the present technique may be applied with respect to a general display apparatus which does not have such a touch sensor function.

In addition, in the above-described embodiments, description has been given of a display apparatus (liquid crystal display apparatus) using a liquid crystal element as a display element; however, the present technique may also be applied to other display elements, for example, a display apparatus using an organic EL element (organic EL display apparatus).

In addition, in the above-described embodiments, description has been given with reference to a display apparatus as an example of an apparatus provided with a semiconductor device (semiconductor circuit unit); however, without being limited thereto, the semiconductor device (semiconductor circuit unit) of the present disclosure may also be applied to an apparatus other than the display apparatus.

Here, the present technique may also adopt the following configuration.

(1) A semiconductor device including: a first electric conductor of a lower layer side and a second electric conductor of an upper layer side; a thick film insulating layer provided between the first electric conductor and the second electric conductor; and a contact portion formed so as to imitate the inner surface shape of a through hole with respect to the insulating layer and electrically connecting the first electric conductor and the second electric conductor, in which the tapered angle of the through hole is an acute angle.

(2) The semiconductor device according to (1) above, in which the tapered angle is greater than 0° and 75° or less.

(3) The semiconductor device according to (1) or (2) above, in which the aspect ratio of the through hole is 0.42 or more.

(4) The semiconductor device according to (3) above, in which the film thickness of the insulating layer is 3 μm or more at least in the vicinity of the forming region of the contact portion.

(5) The semiconductor device according to any one of (1) to (4) above, in which the first conductive film is an electrode of a semiconductor element.

(6) The semiconductor device according to (5) above, in which the semiconductor element is a thin film transistor.

(7) The semiconductor device according to any one of (1) to (6) above, in which the tapered angle is an angle made by the surface of the first electric conductor and the wall surface of the through hole.

(8) A display apparatus including a display unit and a semiconductor circuit unit, in which the semiconductor circuit unit includes: a first electric conductor of a lower layer side and a second electric conductor of an upper layer side, each formed on different layers; a thick film insulating layer provided between the first electric conductor and the second electric conductor; and a contact portion formed so as to imitate the inner surface shape of a through hole with respect to the insulating layer and electrically connecting the first electric conductor and the second electric conductor, in which the tapered angle of the through hole is an acute angle.

(9) The display apparatus according to (8) above, in which the display unit is disposed in an effective display region, and the semiconductor circuit unit is disposed in at least one region of the effective display region and a frame region positioned at the outer edge of the effective display region.

(10) The display apparatus according to (9) above, in which the display unit has a plurality of pixels including various pixel circuits, peripheral circuits are formed in the frame region, and the semiconductor circuit unit is disposed in the pixel circuit and in the peripheral circuit.

(11) The display apparatus according to any one of (8) to (10) above, having a touch sensor function.

(12) The display apparatus according to any one of (8) to (11) above, in which the display unit is configured using a liquid crystal element or an organic EL element.

(13) An electronic apparatus including a display apparatus having a display unit and a semiconductor circuit unit, in which the semiconductor circuit unit includes: a first electric conductor of a lower layer side and a second electric conductor of an upper layer side; a thick film insulating layer provided between the first electric conductor and the second electric conductor; and a contact portion formed so as to imitate the inner surface shape of a through hole with respect to the insulating layer and electrically connecting the first electric conductor and the second electric conductor, in which the tapered angle of the through hole is an acute angle.

(14) A manufacturing method of a semiconductor device including: forming a first electric conductor on a substrate; forming a thick film insulating layer on the first electric conductor; forming a through hole in which the tapered angle is an acute angle in the insulating layer; forming a contact portion electrically connecting with the first electric conductor so as to imitate the inner surface shape of the through hole; and forming a second electric conductor electrically connected to the first electric conductor through the contact portion on the insulating layer.

(15) The manufacturing method for a semiconductor device according to (14) above, in which the through hole is formed by a photolithography technique using halftone exposure.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A semiconductor device comprising:
a first electric conductor of a lower layer side and a second electric conductor of an upper layer side;
a thick film insulating layer provided between the first electric conductor and the second electric conductor; and
a contact portion formed so as to imitate an inner surface shape of a through hole with respect to the insulating layer and electrically connecting the first electric conductor and the second electric conductor,
wherein a tapered angle of the through hole is an acute angle.

2. The semiconductor device according to claim 1, wherein the tapered angle is greater than 0° and 75° or less.

3. The semiconductor device according to claim 1, wherein the aspect ratio of the through hole is 0.42 or more.

4. The semiconductor device according to claim 3, wherein a film thickness of the insulating layer is 3 μm or more at least in a vicinity of a forming region of the contact portion.

5. The semiconductor device according to claim 1, wherein the first conductive film is an electrode of a semiconductor element.

6. The semiconductor device according to claim 5, wherein the semiconductor element is a thin film transistor.

7. The semiconductor device according to claim 1, wherein the tapered angle is an angle made by a surface of the first electric conductor and a wall surface of the through hole.

8. A display apparatus comprising a display unit and a semiconductor circuit unit,
wherein the semiconductor circuit unit includes:
a first electric conductor of a lower layer side and a second electric conductor of an upper layer side;
a thick film insulating layer provided between the first electric conductor and the second electric conductor; and
a contact portion formed so as to imitate the inner surface shape of a through hole with respect to the insulating layer and electrically connecting the first electric conductor and the second electric conductor, and
a tapered angle of the through hole is an acute angle.

9. The display apparatus according to claim 8,
wherein the display unit is disposed in an effective display region, and
the semiconductor circuit unit is disposed in at least one region of the effective display region and a frame region positioned at an outer edge of the effective display region.

10. The display apparatus according to claim 9,
wherein the display unit has a plurality of pixels including various pixel circuits,
peripheral circuits are formed in the frame region, and
the semiconductor circuit unit is disposed in the pixel circuit and in the peripheral circuit.

11. The display apparatus according to claim 8, having a touch sensor function.

12. The display apparatus according to claim 8, wherein the display unit is configured using a liquid crystal element or an organic EL element.

13. An electronic apparatus comprising a display apparatus having a display unit and a semiconductor circuit unit,
wherein the semiconductor circuit unit includes:
a first electric conductor of a lower layer side and a second electric conductor of an upper layer side;
a thick film insulating layer provided between the first electric conductor and the second electric conductor; and
a contact portion formed so as to imitate the inner surface shape of a through hole with respect to the insulating layer and electrically connecting the first electric conductor and the second electric conductor, and
a tapered angle of the through hole is an acute angle.

14. A manufacturing method of a semiconductor device comprising:
forming a first electric conductor on a substrate;
forming a thick film insulating layer on the first electric conductor;
forming a through hole in which the tapered angle is an acute angle in the insulating layer;
forming a contact portion electrically connecting with the first electric conductor so as to imitate the inner surface shape of the through hole; and
forming a second electric conductor electrically connected to the first electric conductor through the contact portion on the insulating layer.

15. The manufacturing method for a semiconductor device according to claim 14, wherein the through hole is formed by a photolithography technique using halftone exposure.
